(19) United States
(12) Patent Application Publication
(10) Pub. No.: US 2008/0028343 A1
(43) Pub. Date: Jan. 31, 2008

(54) SEMICONDUCTOR INTEGRATED CIRCUIT AND METHOD OF DESIGNING THE SAME

(75) Inventors: Hironori Sato, Kawasaki-Shi (JP); Takeshi Kitahara, Kawasaki-Shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/779,366

(22) Filed: Jul. 18, 2007

(30) Foreign Application Priority Data
Jul. 25, 2006 (JP) 2006-202274

(51) Int. Cl. H03L 7/00; G06F 17/50

(52) U.S. Cl. 716/2; 327/141

(57) ABSTRACT

A semiconductor integrated circuit comprising: a clock gating cell to which an enable signal and a clock signal are input, so as to output a gated clock signal generated by output-controlling said clock signal according to said enable signal; a first flip-flop circuit to which a first input data signal and said gated clock signal are input, so as to retain and output said first input data signal as a first output data signal in synchronization with said gated clock signal; and a second flip-flop circuit to which a second input data signal is input, so as to retain and output said second input data signal as a second output data signal in synchronization with said clock signal if the logical values of said second input data signal and said second output data signal differ from each other, or so as to retain said second output data signal if the logical values of said second input data signal and said second output data signal are the same.

### CROSS REFERENCE TO RELATED APPLICATIONS

This application is based upon and claims the benefit of priority from the prior Japanese Patent Application No. 2006-202274, filed on Jul. 25, 2006, the entire contents of which are incorporated herein by reference.

### BACKGROUND OF THE INVENTION

1. Field of the Invention

The present invention relates to a semiconductor integrated circuit and a method of designing the same.

2. Related Art

Since a clock is always on within a semiconductor integrated circuit, large amounts of power are consumed at flip-flop circuits and clock trees. As a flip-flop circuit for reducing power consumption, there is a low power consumption flip-flop (conditional clocking flip-flop, hereinafter referred to as a CCK-FF) (refer to, for example, Japanese Patent Laid-Open No. 2004-56667). The CCK-FF is a flip-flop circuit of master-slave type having first and second latch circuits and is provided with clock control circuits which compare between the input and output of a master unit (first latch circuit) and between the input and output of a slave unit (second latch circuit), do not supply a clock signal to either of the latch circuits if the input and output of each latch circuit take the same logical value, and supply a clock signal to each of the latch circuits if the input and output take different logical values.

A reduction in power consumption is also possible by using a clock signal to which gating is applied (gated clock signal). This is achieved by controlling a supply of clock signals to flip-flop circuits using clock gating cells. The flip-flop circuits are supplied with clock signals only if data transfer is required and are not supplied with clock signals if data transfer is not required.

However, the CCK-FF has the problems described hereinafter if a gated clock signal is applied thereto. In most cases, the gated clock signal rises only once every several times, which means that the gated clock signal remains at a low level most of the time. The clock control circuits of the CCK-FF are designed to detect whether or not an input signal and an output signal agree with each other and, if they agree, do not supply a clock signal. Consequently, the CCK-FF does not provide the effect of power consumption reduction for clock signals gated and kept at a low level most of the time. Furthermore, since the CCK-FF is configured by adding clock control circuits to a normal flip-flop circuit, the circuit area of the CCK-FF becomes larger than that of the normal flip-flop circuit. Still furthermore, since the number of elements increases, the CCK-FF has a leakage current overhead problem. In other words, if a gated clock signal is applied to the CCK-FF, the CCK-FF has the problem that the circuit area thereof increases more than when the gated clock signal is applied to a normal flip-flop circuit, thereby failing to provide the effect of power consumption reduction.

### SUMMARY OF THE INVENTION

According to one aspect of the present invention, there is provided a semiconductor integrated circuit comprising:

a clock gating cell to which an enable signal and a clock signal are input, so as to output a gated clock signal generated by output-controlling said clock signal according to said enable signal;

a first flip-flop circuit to which a first input data signal and said gated clock signal are input, so as to retain and output said first input data signal as a first output data signal in synchronization with said gated clock signal; and

a second flip-flop circuit to which a second input data signal is input, so as to retain and output said second input data signal as a second output data signal in synchronization with said clock signal if the logical values of said second input data signal and said second output data signal differ from each other, or so as to retain said second output data signal if the logical values of said second input data signal and said second output data signal are the same.

According to one aspect of the present invention, there is provided a method of designing a semiconductor integrated circuit comprising:

performing the cell placement of said semiconductor integrated circuit using a clock gating cell to which an enable signal and a clock signal are input, so as to output a gated clock signal generated by output-controlling said clock signal according to said enable signal and a first flip-flop circuit to which a first input data signal and said clock signal or said gated clock signal are input, so as to retain and output said first input data signal as a first output data signal in synchronization with said clock signal or said gated clock signal;

replacing said first flip-flop circuit to which said gated clock signal is not input with a second flip-flop circuit to which a second input data signal is input, so as to retain and output said second input data signal as a second output data signal in synchronization with said clock signal if the logical values of said second input data signal and said second output data signal differ from each other, or so as to retain said second output data signal if the logical values of said second input data signal and said second output data signal are the same; and

performing timing optimization processing.

According to one aspect of the present invention, there is provided a method of designing a semiconductor integrated circuit comprising:

performing the cell placement of said semiconductor integrated circuit using a clock gating cell to which an enable signal and a clock signal are input, so as to output a gated clock signal generated by output-controlling said clock signal according to said enable signal and a first flip-flop circuit to which a first input data signal and said clock signal or said gated clock signal are input, so as to retain and output said first input data signal as a first output data signal in synchronization with said clock signal or said gated clock signal; and

replacing said first flip-flop circuit to which said gated clock signal is not input and in which the timing margin of a path connected to said first flip-flop circuit is no smaller than a predetermined value, with a second flip-flop circuit to which a second input data signal is input, so as to retain and output said second input data signal as a second output data signal in synchronization with said clock signal if the logical values of said second input data signal and said second output data signal differ from each other, or so as to retain the output of said second output data signal if the logical values of said second input data signal and said second output data signal are the same.

### BRIEF DESCRIPTION OF THE DRAWINGS

FIG. 1 is a block diagram illustrating a schematic configuration of a semiconductor integrated circuit in accordance with the first embodiment of the present invention;

FIG. 2 is a block diagram illustrating a schematic configuration of flip-flop circuits in the semiconductor integrated circuit in accordance with the first embodiment of the present invention;

FIG. 3 is a block diagram illustrating a schematic configuration of a clock gating cell in the semiconductor integrated circuit in accordance with the first embodiment of the present invention;

FIG. 4 is a block diagram illustrating a schematic configuration of a low power consumption flip-flop circuit in the semiconductor integrated circuit in accordance with the first embodiment of the present invention;

FIG. 5 is a schematic view illustrating a flowchart of a method of designing a semiconductor integrated circuit in accordance with the second embodiment of the present invention;

FIG. 6 is a schematic view illustrating a flowchart of a method of designing a semiconductor integrated circuit in accordance with the third embodiment of the present invention;

FIG. 7 is a schematic view illustrating a flowchart of a method of designing a semiconductor integrated circuit in accordance with the fourth embodiment of the present invention and

FIG. 8 is a schematic view illustrating a flowchart of a method of designing a semiconductor integrated circuit in accordance with the fifth embodiment of the present invention.

### DETAILED DESCRIPTION OF THE INVENTION

A description will hereinafter be made of a semiconductor integrated circuit and a method of designing the semiconductor integrated circuit in accordance with embodiments of the present invention with reference to the accompanying drawings.

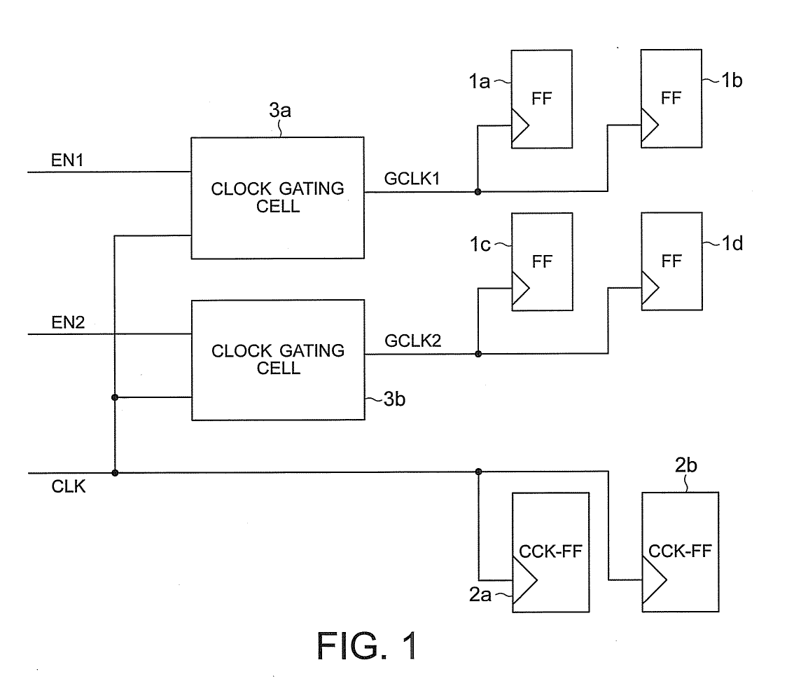

(First Embodiment) FIG. 1 is a block diagram illustrating a schematic configuration of a semiconductor integrated circuit in accordance with the first embodiment of the present invention. The semiconductor integrated circuit is provided with a flip-flop (FF) circuit 1, a low power consumption flip-flop (CCK-FF) circuit 2 and a clock gating cell 3.

A clock signal CLK and an enable signal EN1 are input to a clock gating cell 3a and a gated clock signal GCLK1 is output from the clock gating cell 3a. The gated clock signal GCLK1 is input to flip-flop circuits 1a and 1b.

The clock signal CLK and an enable signal EN2 are input to a clock gating cell 3b and a gated clock signal GCLK2 is output from the clock gating cell 3b. The gated clock signal GCLK2 is input to flip-flop circuits 1c and 1d.

The clock signal CLK is input to low power consumption flip-flop circuits 2a and 2b.

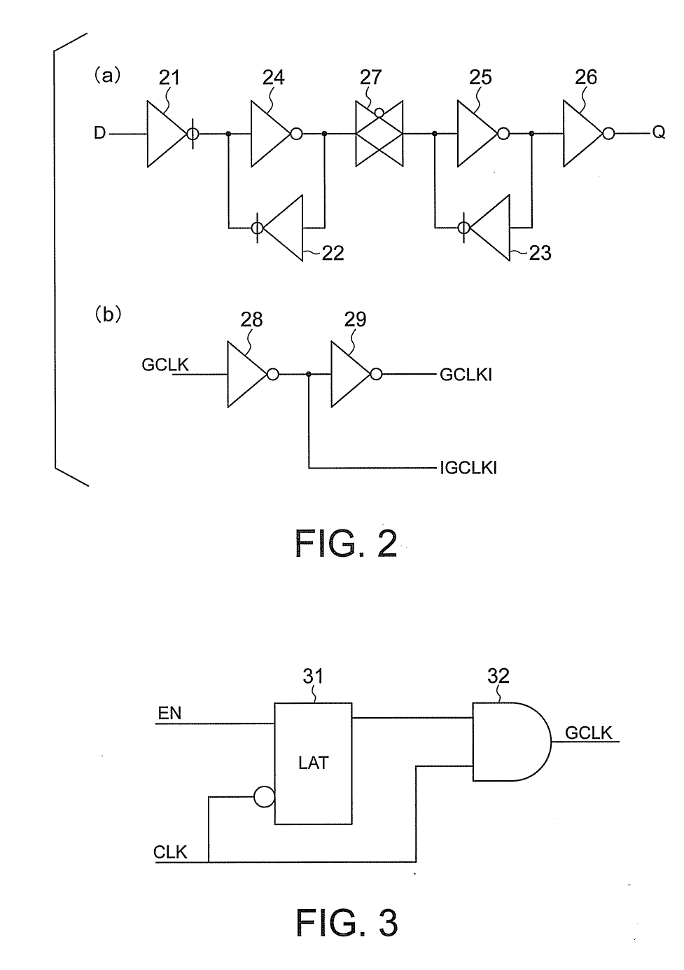

FIG. 2 illustrates the circuit diagram of the flip-flop circuit 1. FIG. 2a illustrates the signal transmission circuit of the flip-flop circuit and FIG. 2b illustrates the clock supply circuit of the flip-flop circuit. The signal transmission circuit of the flip-flop circuit has clocked inverters 21 to 23, inverters 24 to 26 and a transmission gate 27.

The input of the clocked inverter 21 is connected to a D input. The output of the clocked inverter 21 is connected to the input of the inverter 24 and to the output of the clocked inverter 22. The output of the inverter 24 and the input of the clocked inverter 22 are connected to the input of the transmission gate 27. The output of the transmission gate 27 is connected to the input of the inverter 25 and to the output of the clocked inverter 23. The output of the inverter 25 and the input of the clocked inverter 23 are connected to the input of the inverter 26 and the output of the inverter 26 is connected to a Q output.

The clock supply circuit of the flip-flop circuit has inverters 28 and 29. The input of the inverter 28 is connected to the supply node of the gated clock signal GCLK and the input of the inverter 29 is connected to the output of the inverter 28. An internal clock signal GCLKI is supplied from the output of the inverter 29 and an inverted internal clock signal /GCLKI is supplied from the output of the inverter 28.

The clocked inverter 22 operates as an inverter when the internal clock signal GCLKI is at a high (H) level and sets its output to a high-impedance state when the internal clock signal GCLKI is at a low (L) level, thereby decoupling the input and output thereof from each other. The clocked inverters 21 and 23 operate as inverters when the internal clock signal GCLKI is at an L level and set their outputs to a high-impedance state when the internal clock signal GCLKI is at an H level, thereby decoupling the inputs and outputs thereof from each other. The transmission gate 27 lets a signal to pass therethrough when the internal clock signal GCLKI is at an H level and prohibits a signal from passing therethrough when the internal clock signal GCLKI is at an L level.

When the gated clock signal GCLK is at an L level, a signal input from the D input passes through the clocked inverter 21 and is input to the inverter 24. Since the internal clock signal GCLKI is at an L level, the transmission gate 27 and the clocked inverter 22 are closed, thereby blocking the input signal.

When the gated clock signal GCLK switches from an L level to an H level, the clocked inverter 21 closes and the transmission gate 27 and the clocked inverter 22 open. In other words, the signal being input from the D input is latched by the inverter 24 and the clocked inverter 22, passes through the transmission gate 27 and the inverters 25 and 26, and is output from the Q output the moment the gated clock signal GCLK switches its level.

Then, when the gated clock signal GCLK switches from an H level to a L level, the transmission gate 27 closes and the clocked inverter 23 opens. As a result, the signal that has passed through the transmission gate 27 is latched by the inverter 25 and the clocked inverter 23, passes through the inverter 26, and is output from the Q output. This condition continues until the transmission gate 27 opens and a signal of a different level is input.

Now, a description will hereinafter be made of a flip-flop circuit wherein a normal flip-flop circuit has such a configuration as described above.

FIG. 3 illustrates a schematic configuration of a clock gating cell 3. The clock gating cell has a latch circuit 31 and a logical product (AND) circuit 32. An enable signal EN and a clock signal CLK are input to the latch circuit 31. The output of the latch circuit 31 and the clock signal CLK are input to the AND circuit 32. By configuring the clock gating cell 3 as described above, the gated clock signal GCLK is output from the AND circuit 32.

The signal transmission circuits of the flip-flop circuits 1a to 1d operate in synchronization with an internal clock signal and an inverted internal clock signal generated from gated clock signals GCLK1 and GCLK2. The clock gating cell 3a is controlled by the enable signal EN1, so as to supply a clock signal if data transmission is required at the flip-flop circuits 1a and 1b , or so as not to supply a clock signal when data transmission is not required. In addition, the clock gating cell 3b is controlled by the enable signal EN2, so as to supply a clock signal if data transmission is required at the flip-flop circuits 1c and 1d, or so as not to supply a clock signal if data transmission is not required. As a result, it is possible to suppress power consumption since the flip-flop circuits 1a to 1d are not supplied with a clock signal and are therefore disabled when data transmission is required.

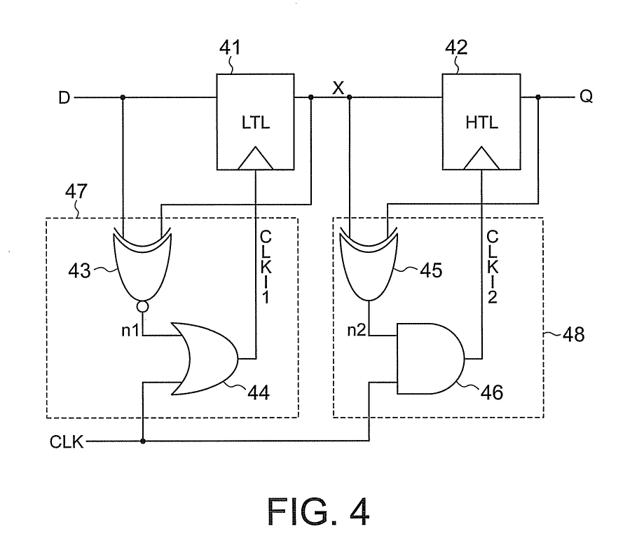

FIG. 4 illustrates a schematic configuration of a low power consumption flip-flop (CCK-FF) circuit 2. The low power consumption flip-flop circuit has latch circuits 41 and 42, a two-input exclusive negative logical sum (EX-NOR) circuit 43, a two-input logical sum (OR) circuit 44, a two-input exclusive logical sum (EX-OR) circuit 45, and a two-input logical product (AND) circuit 46.

The input node of the latch circuit 41 is connected to the D input and the output node thereof is connected to a node X. The input node of the latch circuit 42 is connected to the node X and the output node thereof is connected to the Q output. One input of the EX-NOR circuit 43 is connected to the D input and the other input thereof is connected to the node X. The output n1 of the EX-NOR circuit 43 and the clock signal CLK are input to the OR circuit 44 and a first internal clock signal CLKI1 is output therefrom.

One input of the EX-OR circuit 45 is connected to the Q output and the other input thereof is connected to the node X. The output n2 of the EX-OR circuit 45 and the clock signal CLK are input to the AND circuit 46 and a second internal clock signal CLKI2 is output therefrom.

The latch circuit 41 lets a signal pass therethrough while the clock signal being input is at an L level and retains the signal while the clock signal is at an H level. In addition, the latch circuit 42 lets a signal pass therethrough while the clock signal being input is at an H level and retains the signal while the clock signal is at an L level.

Now an explanation will be made of the operation of the low power consumption flip-flop (CCK-FF) circuit configured as described above. If the logical values of the D input, node X and Q output are the same, the output n1 of the EX-NOR circuit 43 goes to an H level. Since this H-level output n1 is input to the OR circuit 44, the internal clock signal CLKI1 output from the OR circuit 44 and input to the latch circuit 41 is always at an H level and the latch circuit 41 retains the signal. In addition, the output n2 of the EX-OR circuit 45 goes to an L level. Since this L-level output n2 is input to the AND circuit 46, the internal clock signal CLKI2 output from the AND circuit 46 and input to the latch circuit 42 is always at an L level and the latch circuit 42 retains the signal. Consequently, the clock signal CLK is blocked by the OR circuit 44 and the AND circuit 46 from being input to the latch circuits 41 and 42.

Assume here that the logical value of the D input has changed. Since the logical values of the D input applied to the EX-NOR circuit 43 and of the node X differ from each other, the output n1 of the EX-NOR circuit 43 goes to an L level. This L-level output n1 is input to the OR circuit 44, thereby causing the internal clock signal CLKI1 output from the OR circuit 44 and input to the latch circuit 41 to equal the clock signal CLK. If the clock signal CLK goes to an L level, the latch circuit 41 lets a signal pass therethrough, thereby causing the logical values of the D input and the node X to become equal to each other. Since the logical value of the node X input to the EX-OR circuit 45 differs from the logical value of the Q output, the output n2 of the EX-OR circuit 45 goes to an H level. This H-level output n2 is input to the AND circuit 46, thereby causing the internal clock signal CLKI2 output from the AND circuit 46 and input to the latch circuit 42 to equal the clock signal CLK. If the clock signal CLK goes to an H level, the latch circuit 42 lets a signal to pass therethrough, thereby causing the Q output to take the same logical value as that of the node X. This means that the D input is output from the Q output in synchronization with the rise of the clock signal CLK.

As described above, the low power consumption flip-flop (CCK-FF) circuit is configured so that while operating as a normal D-type flip-flop circuit, the clock signal CLK is blocked by a clock control circuit 47 (EX-NOR circuit 43 and OR circuit 44) from being input to the latch circuit 41 and is also blocked by another clock control circuit 48 (EX-OR circuit 45 and AND circuit 46) from being input to the latch circuit 42, when the D input and the Q output take the same logical value. As a result, it is possible to avoid unnecessary circuit operations and thereby reduce power consumption.

The semiconductor integrated circuit in accordance with the first embodiment of the present invention allows the power consumption thereof to be reduced and the circuit area thereof to be decreased, when compared with a case where low power consumption flip-flop (CCK-FF) circuits are used, by connecting normal flip-flop circuits to the clock gating cells and supplying gated clock signals to the flip-flop circuits. Power consumption can also be reduced by applying low power consumption flip-flop (CCK-FF) circuits to portions supplied with non-gated clock signals.

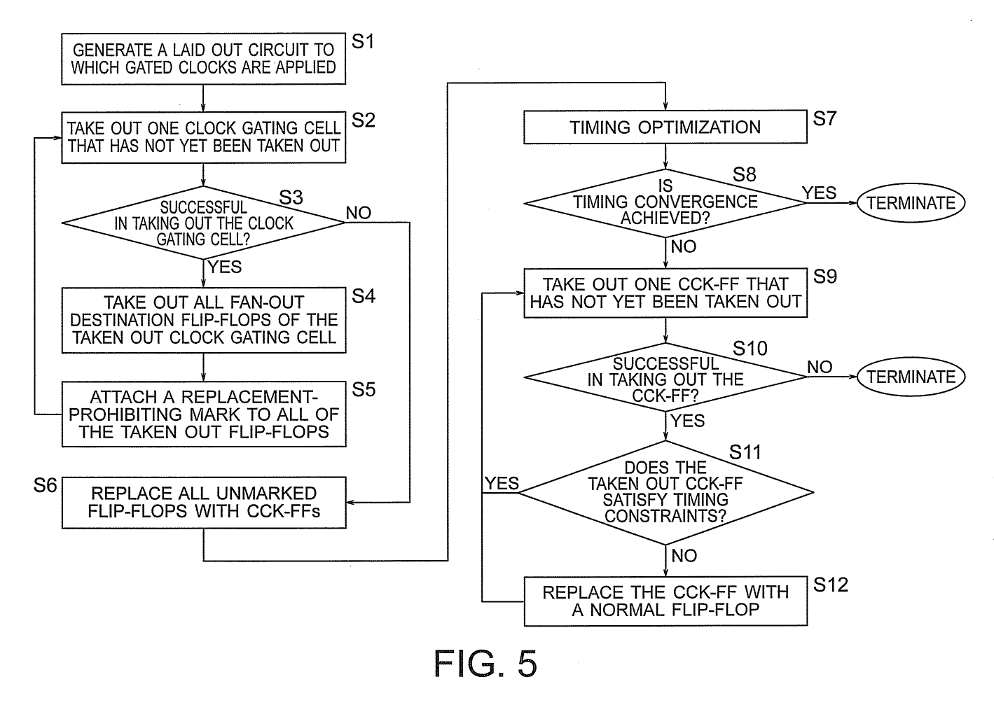

(Second Embodiment) An explanation will be made of a method of designing a semiconductor integrated circuit in accordance with the second embodiment of the present invention with reference to the flowchart shown in FIG. 5.

(Step S1) Using clock gating cells and normal flip-flop circuits, place cells and design a semiconductor integrated circuit, so as to satisfy timing constraints.

(Step S2) Take out one clock gating cell that has not yet been taken out.

(Step S3) If successful in taking out the clock gating cell, go to Step S4. If not successful (all clock gating cells have already been taken out), go to Step S6.

(Step S4) All fan-out destination flip-flops of the taken out clock gating cell are taken out.

(Step S5) The taken out flip-flops are marked. Go back to Step S2.

(Step S6) All unmarked flip-flop circuits are replaced with low power consumption flip-flop (CCK-FF) circuits.

(Step S7) Timing optimization processing is performed. Timing optimization processing refers to a process of searching for paths that do not satisfy user-provided timing constraints (paths where timing errors are present), inserting buffers, deleting unnecessary buffers, performing cell sizing and the like, and performing path optimization according to information, such as wiring delays, wiring loads, cell positions, and the like available from a layout.

(Step S8) Terminate if the timing constraints have been satisfied for all paths (timing convergence has been achieved) by timing optimization processing. If the timing constraints have not been satisfied (timing convergence has not been achieved), go to Step S9.

(Step S9) Take out one low power consumption flip-flop (CCK-FF) circuit that has not yet been taken out.

(Step S10) If successful in taking out the low power consumption flip-flop circuit, go to Step S11. If not successful (all low power consumption flip-flop circuits have already been taken out), terminate.

(Step S11) An examination is made as to whether the taken out low power consumption flip-flop circuit satisfies the timing constraints. If the timing constraints are satisfied, go back to Step S9. If the timing constraints are not satisfied, go to Step S12.

(Step S12) The taken out low power consumption flip-flop circuit is replaced with a normal flip-flop circuit. Go back to Step S9.

According to the above-described steps S1 to S6, it is possible to design such a semiconductor integrated circuit as shown in FIG. 1 wherein gated clock signals are supplied to the normal flip-flop circuits and the non-gated clock signals are supplied to the low power consumption flip-flop (CCK-FF) circuits. In addition, if the semiconductor integrated circuit has any paths that do not satisfy the timing constraints as a result of timing optimization processing, the low power consumption flip-flop circuits that do not satisfy the timing constraints are replaced with normal flip-flop circuits according to Steps S9 to S12. It should be noted here that in Step S1, the semiconductor integrated circuit has been designed, so as to satisfy the timing constraints. Accordingly, the conceivable reason for the semiconductor integrated circuit being no longer able to satisfy the timing constraints is that the normal flip-flop circuits have been replaced with the low power consumption flip-flop circuits in Step S6. Since a normal flip-flop circuit transfers a clock signal faster than a low power consumption flip-flop circuit, the low power consumption flip-flop circuit is replaced with the normal flip-flop circuit to satisfy the timing constraints.

According to the method of designing a semiconductor integrated circuit in accordance with the above-described second embodiment, it is possible to design a semiconductor integrated circuit having a reduced circuit area since portions to be supplied with gated clock signals are normal flip-flop circuits rather than low power consumption flip-flop (CCK-FF) circuits.

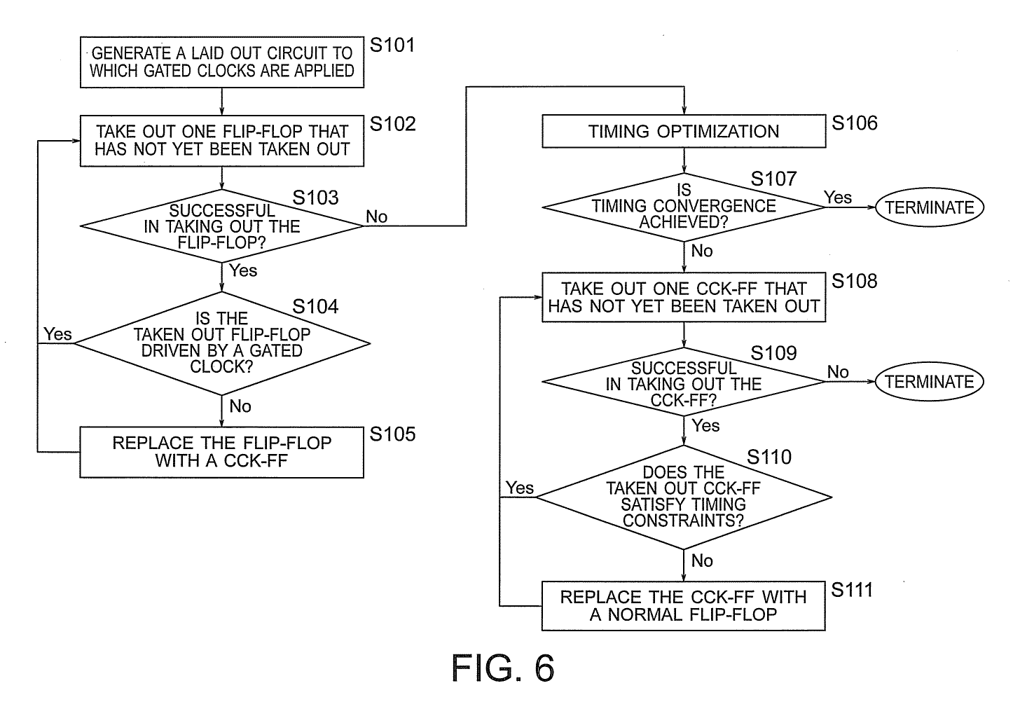

(Third Embodiment) An explanation will be made of a method of designing a semiconductor integrated circuit in accordance with the third embodiment of the present invention with reference to the flowchart shown in FIG. 6.

(Step S101) Using clock gating cells and normal flip-flop circuits, place cells and design a semiconductor integrated circuit, so as to satisfy timing constraints.

(Step S102) Take out one normal flip-flop circuit that has not yet been taken out.

(Step S103) If successful in taking out the normal flip-flop circuit, go to Step S104. If not successful (all normal flip-flop circuits have already been taken out), go to Step S106.

(Step S104) An examination is made as to whether the taken out normal flip-flop circuit is driven by a gated clock signal (whether the taken out normal flip-flop circuit is connected to a clock gating cell). If the normal flip-flop circuit is driven by a gated clock signal, go back to Step S102. If the normal flip-flop circuit is not driven by a gated clock signal, go to Step S105.

(Step S105) The taken out normal flip-flop circuit is replaced with a low power consumption flip-flop (CCK-FF) circuit. Go back to Step S102.

(Step S106) Timing optimization processing is performed.

(Step S107) Terminate if there are no paths that do not satisfy the timing constraints (timing convergence is achieved). If there are any paths that do not satisfy the timing constrains (timing convergence is not achieved), go to Step S108.

(Step S108) Take out one low power consumption flip-flop (CCK-FF) circuit that has not yet been taken out.

(Step S109) If successful in taking out the low power consumption flip-flop circuit, go to Step S110. If not successful (all low power consumption flip-flop circuits have already been taken out), terminate.

(Step S110) An examination is made as to whether the taken out low power consumption flip-flop circuit satisfies the timing constraints. If the timing constraints are satisfied, go back to Step S108. If the timing constraints are not satisfied, go to Step S111.

(Step S111) The taken out low power consumption flip-flop circuit is replaced with a normal flip-flop circuit. Go back to Step S108.

According to the above-described steps S101 to S105, it is possible to design such a semiconductor integrated circuit as shown in FIG. 1 wherein gated clock signals are supplied to the normal flip-flop circuits and the non-gated clock signals are supplied to the low power consumption flip-flop (CCK-FF) circuits.

In addition, if the semiconductor integrated circuit has failed to achieve timing convergence as a result of timing optimization processing, the low power consumption flip-flop circuits that do not satisfy the timing constraints are replaced with normal flip-flop circuits, according to Steps S108 to S111, so that the paths within the semiconductor integrated circuit satisfy the timing constraints.

According to the method of designing a semiconductor integrated circuit in accordance with the above-described third embodiment, it is possible to design a low power consumption semiconductor integrated circuit having a reduced circuit area since portions to be supplied with gated clock signals are normal flip-flop circuits rather than low power consumption flip-flop (CCK-FF) circuits.

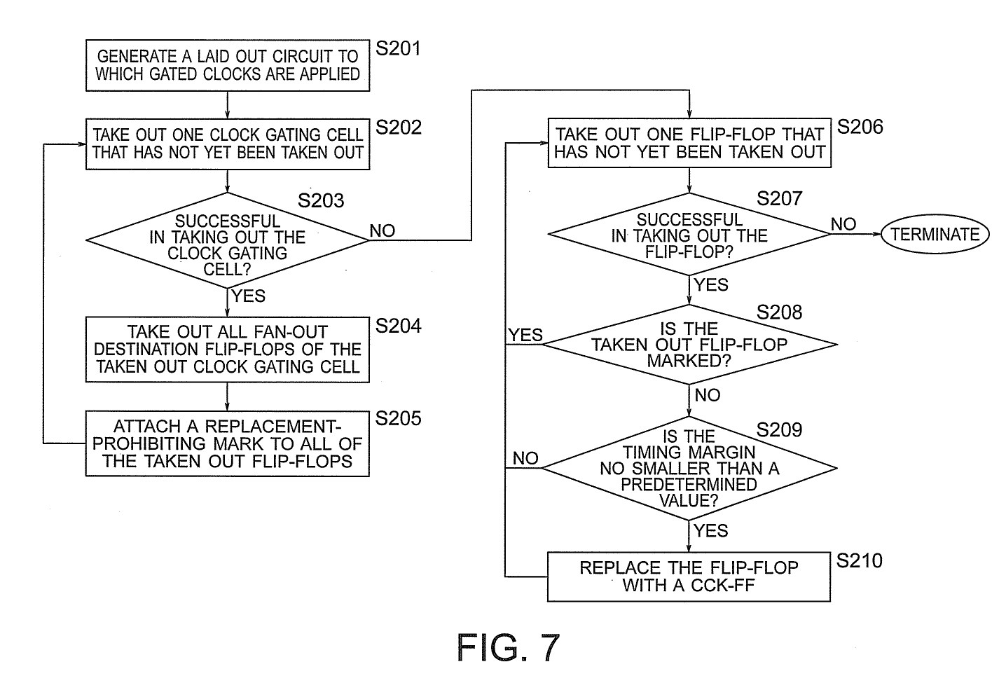

(Fourth Embodiment) An explanation will be made of a method of designing a semiconductor integrated circuit in accordance with the fourth embodiment of the present invention with reference to the flowchart shown in FIG. 7.

(Step S201) Using clock gating cells and normal flip-flop circuits, place cells and design a semiconductor integrated circuit, so as to satisfy timing constraints.

(Step S202) Take out one clock gating cell that has not yet been taken out.

(Step S203) If successful in taking out the clock gating cell, go to Step S204. If not successful (all clock gating cells have already been taken out), go to Step S206.

(Step S204) All fan-out destination flip-flops of the taken out clock gating cell are taken out.

(Step S205) The taken out flip-flop circuits are marked. Go back to Step S202.

(Step S206) Take out one flip-flop circuit that has not yet been taken out.

(Step S207) If successful in taking out the flip-flop circuit, go to Step S208. If not successful (all flip-flop circuits have already been taken out), terminate.

(Step S208) An examination is made as to whether the taken out flip-flop circuit is marked. If the flip-flop circuit is marked, go back to Step S206. If the flip-flop circuit is not marked, go to Step S209.

(Step S209) An examination is made as to whether the timing margin of a path connected to the taken out unmarked flip-flop circuit is no smaller than a predetermined value. If the timing margin is no smaller than the predetermined value, go to Step S210. If the timing margin is smaller than the predetermined value, go back to Step S206. The timing margin is a difference between the setup time of the path in question and a timing constraint specified for the path. The setup time refers to the minimum time required for an input data signal to be defined prior to a clock signal in order to read data.

(Step S210) Replace the taken out unmarked flip-flop circuit with a low power consumption flip-flop (CCK-FF) circuit and go back to Step S206.

A low power consumption flip-flop circuit has clock control circuits and is, therefore, slower in clock signal transfer than a normal flip-flop circuit, thereby requiring a relatively longer setup time. In the above-described design method, there is no need to perform timing optimization processing after replacement and, therefore, it is possible to reduce a time to be involved in circuit design since replacement is made only after examining respective flip-flop circuits not supplied with gated clock signals to determine whether the timing margins of paths to be connected thereto are no smaller than predetermined values, i.e., whether timing constraints can be satisfied even if the flip-flop circuits are replaced with low power consumption flip-flop (CCK-FF) circuits.

According to the method of designing a semiconductor integrated circuit in accordance with the above-described fourth embodiment, it is possible to design a semiconductor integrated circuit having a reduced circuit area since portions to be supplied with gated clock signals are normal flip-flop circuits rather than low power consumption flip-flop (CCK-FF) circuits. It is also possible to reduce a time to be involved in design.

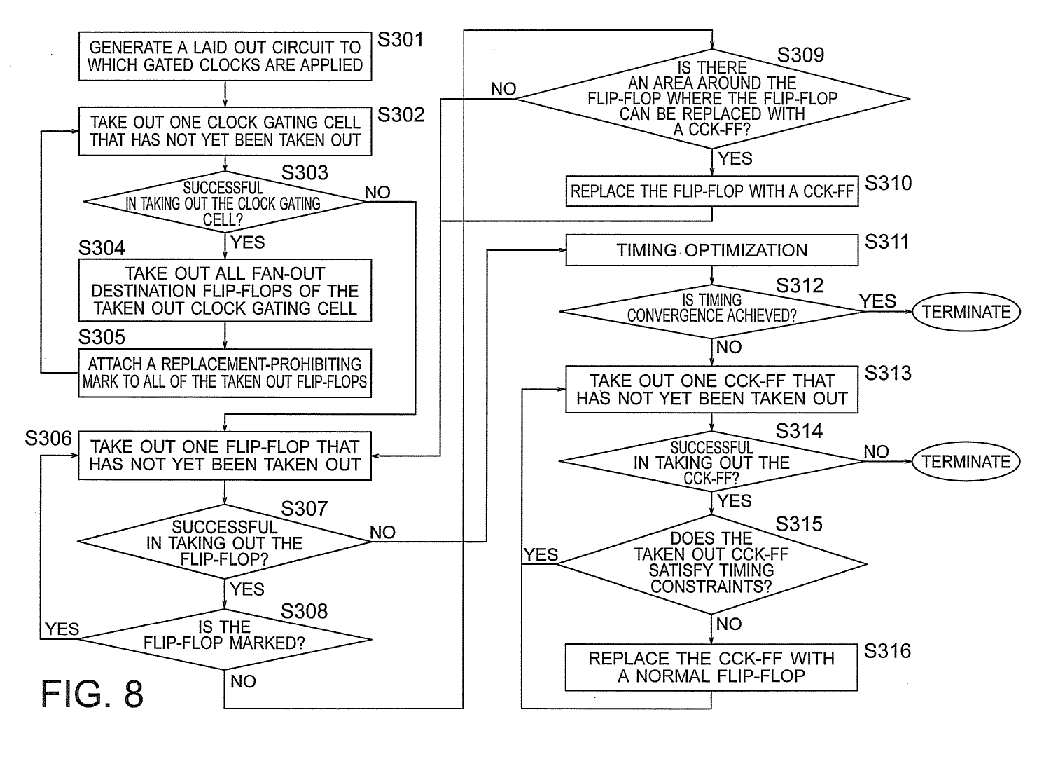

(Fifth Embodiment) An explanation will be made of a method of designing a semiconductor integrated circuit in accordance with the fifth embodiment of the present invention with reference to the flowchart shown in FIG. 8.

(Step S301) Using clock gating cells and normal flip-flop circuits, place cells and design a semiconductor integrated circuit, so as to satisfy timing constraints.

(Step S302) Take out one clock gating cell that has not yet been taken out.

(Step S303) If successful in taking out the clock gating cell, go to Step S304. If not successful (all clock gating cells have already been taken out), go to Step S306.

(Step S304) All fan-out destination flip-flops of the taken out clock gating cell are taken out.

(Step S305) The taken out flip-flop circuits are marked. Go back to Step S302.

(Step S306) Take out one flip-flop circuit that has not yet been taken out.

(Step S307) If successful in taking out the flip-flop circuit, go to Step S308. If not successful (all flip-flop circuits have already been taken out), go to Step S311.

(Step S308) An examination is made as to whether the taken out flip-flop circuit is marked. If the flip-flop circuit is marked, go back to Step S306. If the flip-flop circuit is not marked, go to Step S309.

(Step S309) An examination is made as to whether there is an area around the taken out unmarked flip-flop circuit where a low power consumption flip-flop circuit can be disposed in place of the unmarked flip-flop circuit and wired. If there is such an area, go to Step S310. If there is no such an area, go back to Step S306.

(Step S310) Replace the taken out unmarked flip-flop circuit with a low power consumption flip-flop circuit and go back to Step S3206.

(Step S311) Timing optimization processing is performed.

(Step S312) Terminate if there are no paths that do not satisfy the timing constraints (timing convergence is achieved). If there are any paths that do not satisfy the timing constrains (timing convergence is not achieved), go to Step S313.

(Step S313) Take out one low power consumption flip-flop (CCK-FF) circuit that has not yet been taken out.

(Step S314) If successful in taking out the low power consumption flip-flop circuit, go to Step S315. If not successful (all low power consumption flip-flop circuits have already been taken out), terminate.

(Step S315) An examination is made as to whether the taken out low power consumption flip-flop circuit satisfies the timing constraints. If the timing constraints are satisfied, go back to Step S313. If the timing constraints are not satisfied, go to Step S316.

(Step S316) The taken out low power consumption flip-flop circuit is replaced with a normal flip-flop circuit. Go back to Step S313.

A low power consumption flip-flop circuit has clock control circuits and, therefore, has a circuit area larger than that of a normal flip-flop circuit. In the above-described design method, this logic is taken into consideration (Steps S306 to S310) to perform circuit design.

According to the method of designing a semiconductor integrated circuit in accordance with the above-described fifth embodiment, it is possible to design a low power consumption semiconductor integrated circuit having a reduced circuit area since portions to be supplied with gated clock signals are normal flip-flop circuits rather than low power consumption flip-flop (CCK-FF) circuits.

Each of the above-described embodiments should be considered only as illustrative and not restrictive. For example, in the method of designing a semiconductor integrated circuit in accordance with the above-described third embodiment, there may be added a step of examining whether there is an area around the taken out normal flip-flop circuit where a low power consumption flip-flop circuit can be disposed in place of the normal flip-flop circuit, between Step S104 wherein an examination is made as to whether the taken out normal flip-flop circuit is driven by a gated clock signal (whether the flip-flop circuit is connected to a clock gating cell) and Step S105 wherein the taken out normal flip-flop circuit is replaced with a low power consumption flip-flop circuit.

Furthermore, in the method of designing a semiconductor integrated circuit in accordance with the above-described fourth embodiment, there may be added a step of examining whether there is an area around the taken out unmarked flip-flop circuit where a low power consumption flip-flop circuit can be disposed in place of the unmarked flip-flop circuit and wired, between Step S209 wherein an examination is made as to whether the timing margin of a path connected to the taken out unmarked flip-flop circuit is no smaller than a predetermined value and Step S210 wherein the taken out unmarked flip-flop circuit is replaced with a low power consumption flip-flop (CCK-FF) circuit.

What is claimed is:

1. A semiconductor integrated circuit comprising:
a clock gating cell to which an enable signal and a clock signal are input, so as to output a gated clock signal generated by output-controlling said clock signal according to said enable signal;
a first flip-flop circuit to which a first input data signal and said gated clock signal are input, so as to retain and output said first input data signal as a first output data signal in synchronization with said gated clock signal; and
a second flip-flop circuit to which a second input data signal is input, so as to retain and output said second input data signal as a second output data signal in synchronization with said clock signal if the logical values of said second input data signal and said second output data signal differ from each other, or so as to retain said second output data signal if the logical values of said second input data signal and said second output data signal are the same.

2. The semiconductor integrated circuit according to claim 1, wherein said second flip-flop circuit includes:
a first latch circuit to which said second input data signal and a first internal clock signal are input, so as to let pass therethrough or retain a signal depending on the logical value of said first internal clock signal;
a second latch circuit to which the output signal of said first latch circuit and a second internal clock signal are input, so as to retain or let pass therethrough a signal according to operating characteristics opposite to those of said first latch circuit, depending on the logical value of said second internal clock signal, and output said second output data signal;
a first clock control circuit to which said second input data signal, said clock signal and the output signal of said first latch circuit are provided, so as to compare between the signal logical values of said second input data signal and of the output signal of said first latch circuit, and output a specific logical value signal for retaining a signal as said first internal clock signal if said signal logical values are the same, or output said clock signal as said first internal clock signal if said signal logical values differ from each other; and
a second clock control circuit to which the output signal of said first latch circuit, said clock signal and said second output data signal are provided, so as to compare between the signal logical values of the output signal of said first latch circuit and of said second output data signal, and output a specific logical value signal for retaining a signal as said second internal clock signal if said signal logical values are the same, or output said clock signal as said second internal clock signal if said signal logical values differ from each other.

3. The semiconductor integrated circuit according to claim 2, wherein said first latch circuit lets a signal pass therethrough while said first internal clock signal is at a first signal level and retains a signal while said first internal clock signal is at a second signal level, whereas said second latch circuit lets a signal pass therethrough while said second internal clock signal is at said second signal level and retains a signal while said second internal clock signal is at said first signal level.

4. The semiconductor integrated circuit according to claim 2, wherein said first clock control circuit has an EXNOR circuit to which said second input data signal and the output signal of said first latch circuit are input, so as to compare between the signal logical values thereof.

5. The semiconductor integrated circuit according to claim 4, wherein said first clock control circuit has an OR circuit to which the output signal of said EXNOR circuit and said clock signal are input, so as to output said first internal clock signal.

6. The semiconductor integrated circuit according to claim 4, wherein said second clock control circuit has an EXOR circuit to which the output signal of said first latch circuit and said second output data signal are input, so as to compare between the signal logical values thereof.

7. The semiconductor integrated circuit according to claim 6, wherein said second clock control circuit has an AND circuit to which the output signal of said EXOR circuit and said clock signal are input, so as to output said second internal clock signal.

8. The semiconductor integrated circuit according to claim 1, wherein said clock gating cell includes:
a latch circuit to which said enable signal and said clock signal are input; and
an AND circuit to which the output signal of said latch circuit and said clock signal are input, so as to output said gated clock signal.

9. The semiconductor integrated circuit according to claim 1, wherein said first flip-flop circuit includes:
a signal transmission circuit to which said first input data signal is input, so as to retain and output said first input data signal as said first output data signal in synchronization with an internal clock signal or an inverted internal clock signal; and
a clock supply circuit to which said gated clock signal is input, so as to supply said internal clock signal and said inverted internal clock signal synchronized with said gated clock signal to said signal transmission circuit.

10. The semiconductor integrated circuit according to claim 9, wherein said signal transmission circuit includes:
a first clocked inverter to which said first input data signal is input;
a first inverter to which the output of said first clocked inverter is provided;
a second clocked inverter, the input terminal thereof being connected to the output terminal of said first inverter and the output terminal thereof being connected to the input terminal of said first inverter and to the output terminal of said first clocked inverter;
a transmission gate, the input terminal thereof being connected to the output terminal of said first inverter and to the input terminal of said second clocked inverter;
a second inverter, the input terminal thereof being connected to the output terminal of said transmission gate;
a third clocked inverter, the input terminal thereof being connected to the output terminal of said second inverter and the output terminal thereof being connected to the input terminal of said second inverter and to the output terminal of said transmission gate; and
a third inverter, the input terminal thereof being connected to the output terminal of said second inverter and to the input terminal of said third clocked inverter, so as to output said first output data signal.

11. The semiconductor integrated circuit according to claim 9, wherein said clock supply circuit includes:
a fourth inverter to which said gated clock signal is input, so as to output said inverted internal clock signal; and
a fifth inverter, the input terminal thereof being connected to the output terminal of said fourth inverter so as to output said internal clock signal.

12. A method of designing a semiconductor integrated circuit comprising:
performing the cell placement of said semiconductor integrated circuit using a clock gating cell to which an enable signal and a clock signal are input, so as to output a gated clock signal generated by output-controlling said clock signal according to said enable signal and a first flip-flop circuit to which a first input data signal and said clock signal or said gated clock signal are input, so as to retain and output said first input data signal as a first output data signal in synchronization with said clock signal or said gated clock signal;
replacing said first flip-flop circuit to which said gated clock signal is not input with a second flip-flop circuit to which a second input data signal is input, so as to retain and output said second input data signal as a second output data signal in synchronization with said clock signal if the logical values of said second input data signal and said second output data signal differ from each other, or so as to retain said second output data signal if the logical values of said second input data signal and said second output data signal are the same; and
performing timing optimization processing.

13. The method of designing a semiconductor integrated circuit according to claim 12, wherein said replacing said first flip-flop circuit to which said gated clock signal is not input with said second flip-flop circuit includes:
taking out said clock gating cells one at a time and marking said first flip-flop circuits of the fan-out destination of each of said clock gating cell; and
replacing said first flip-flop circuits which have not been marked with said second flip-flop circuits.

14. The method of designing a semiconductor integrated circuit according to claim 12, wherein said replacing said first flip-flop circuit to which said gated clock signal is not input with said second flip-flop circuit includes:
taking out said clock gating cells one at a time and marking said first flip-flop circuits of the fan-out destination of each of said clock gating cell; and
taking out said first flip-flop circuits which have not been marked, one at a time, detecting whether there is an area where said second flip-flop circuits can be disposed in place of said first flip-flop circuits, and making replacement if there is said area.

15. The method of designing a semiconductor integrated circuit according to claim 12, wherein said replacing said first flip-flop circuit to which said gated clock signal is not input with said second flip-flop circuit includes:
taking out said first flip-flop circuits one at a time and detecting whether said gated clock signal is input thereto; and
replacing said first flip-flop circuit with said second flip-flop circuit if said gated clock signal is not input to said first flip-flop circuit.

16. The method of designing a semiconductor integrated circuit according to claim 12, wherein said replacing said first flip-flop circuit to which said gated clock signal is not input with said second flip-flop circuit includes:
taking out said first flip-flop circuits one at a time and detecting whether said gated clock signal is input thereto; and
detecting whether there is an area where said second flip-flop circuits can be disposed in place of said first flip-flop circuits to which said gated clock signal is not input, and making replacement if there is said area.

17. The method of designing a semiconductor integrated circuit according to claim 12, further comprising the steps of detecting whether there are any paths in said semiconductor integrated circuit that do not satisfy timing constraints after said step of performing timing optimization processing, taking out said second flip-flop circuits one at a time if there are any paths that do not satisfy timing constraints, detecting whether each of said paths satisfies timing constraints, and replacing said second flip-flop circuits that do not satisfy timing constraints with said first flip-flop circuits.

18. A method of designing a semiconductor integrated circuit comprising:
performing the cell placement of said semiconductor integrated circuit using a clock gating cell to which an enable signal and a clock signal are input, so as to output a gated clock signal generated by output-controlling said clock signal according to said enable signal and a first flip-flop circuit to which a first input data signal and said clock signal or said gated clock signal are input, so as to retain and output said first input data signal as a first output data signal in synchronization with said clock signal or said gated clock signal; and
replacing said first flip-flop circuit to which said gated clock signal is not input and in which the timing margin of a path connected to said first flip-flop circuit is no smaller than a predetermined value, with a second flip-flop circuit to which a second input data signal is input, so as to retain and output said second input data signal as a second output data signal in synchronization with said clock signal if the logical values of said second input data signal and said second output data signal differ from each other, or so as to retain the output of said second output data signal if the logical values of said second input data signal and said second output data signal are the same.

19. The method of designing a semiconductor integrated circuit according to claim 18, wherein said replacing said first flip-flop circuit to which said gated clock signal is not input and in which the timing margin of a path connected to said first flip-flop circuit is no smaller than a predetermined value, with a second flip-flop circuit includes:
taking out said clock gating cells one at a time and marking said first flip-flop circuits of the fan-out destination of each of said clock gating cell; and
taking out said first flip-flop circuits which have not been marked, one at a time, detecting the timing margin of a path to which each of said first flip-flop circuits is connected, and replacing said first flip-flop circuits with said second flip-flop circuits if said timing margin is no smaller than said predetermined value.

20. The method of designing a semiconductor integrated circuit according to claim 18, wherein said replacing said first flip-flop circuit to which said gated clock signal is not input and in which the timing margin of a path connected to said first flip-flop circuit is no smaller than a predetermined value, with a second flip-flop circuit includes:
taking out said clock gating cells one at a time and marking said first flip-flop circuits of the fan-out destination of each of said clock gating cell;
taking out said first flip-flop circuits which have not been marked, one at a time, detecting the timing margin of a path to which each of said first flip-flop circuits is connected; and
detecting whether there is an area where said second flip-flop circuit can be disposed in place of said first flip-flop circuit in which said timing margin is no smaller than a predetermined value, and making replacement if there is said area.
